(19) United States
(12) Patent Application Publication
(10) Pub. No.: US 2012/0093186 A1
(43) Pub. Date: Apr. 19, 2012

(54) NITRIDE-BASED SEMICONDUCTOR LASER ELEMENT AND OPTICAL APPARATUS

(75) Inventor: Yoshiki MURAYAMA, Tottori-shi (JP)

(73) Assignee: Sanyo Electric Co., Ltd., Moriguchi-shi (JP)

(21) Appl. No.: 13/273,617

(22) Filed: Oct. 14, 2011

(30) Foreign Application Priority Data
Oct. 14, 2010 (JP) 2010-231045

(51) Int. Cl. H01S 5/02

(52) U.S. Cl. 372/44.01

(57) ABSTRACT

This nitride-based semiconductor laser element includes a semiconductor element layer made of a nitride-based semiconductor having an emitting-side cavity facet and a reflecting-side cavity facet, and a facet coating film formed on the emitting-side cavity facet. The facet coating film has a first dielectric film made of aluminum nitride formed in contact with the emitting-side cavity facet, a second dielectric film made of aluminum oxynitride formed on a side of the first dielectric film opposite to the emitting-side cavity facet, a third dielectric film made of aluminum oxide formed on a side of the second dielectric film opposite to the first dielectric film, a fourth dielectric film made of aluminum oxynitride formed on a side of the third dielectric film opposite to the second dielectric film, and a fifth dielectric film made of aluminum oxide formed on a side of the fourth dielectric film opposite to the third dielectric film.

### CROSS-REFERENCE TO RELATED APPLICATION

The priority application number JP2010-231045, Nitride-Based Semiconductor Laser Element and Optical Apparatus, Oct. 14, 2010, Yoshiki Murayama, upon which this patent application is based is hereby incorporated by reference.

### BACKGROUND OF THE INVENTION

1. Field of the Invention

The present invention relates to a nitride-based semiconductor laser element and an optical apparatus, and more particularly, it relates to a nitride-based semiconductor laser element and an optical apparatus each having dielectric films formed on an emitting-side cavity facet.

2. Description of the Background Art

In recent years, a semiconductor laser has been widely employed as a light source for an optical disk system or an optical communication system. Following improvement in performance of apparatuses constituting the system, improvement in laser element characteristics is desired. In particular, wavelength shortening of a laser beam and a higher laser output are desired in order to serve as a light source for a high-density optical disk system, and a violet semiconductor laser element having a lasing wavelength of about 405 nm has been recently developed with a nitride-based semiconductor.

Japanese Patent Laying-Open No. 2006-203162 discloses a nitride-based semiconductor laser element including a facet coating film, consisting of a dielectric film of Al₂O₃ or the like, formed on a facet of a cavity and having an adhesion layer of AlN formed between the facet of the cavity and the facet coating film.

In the nitride-based semiconductor laser element disclosed in Japanese Patent Laying-Open No. 2006-203162, the thickness of the facet coating film may be set to at least 100 nm, when the same is adjusted in order to control reflectance. In this case, stress on the facet coating film so increases that the facet coating film easily separates from the facet of the cavity. Consequently, the reflectance on the cavity facet so fluctuates that the intensity of a laser beam is disadvantageously unstabilized.

### SUMMARY OF THE INVENTION

A nitride-based semiconductor laser element according to a first aspect of the present invention includes a semiconductor element layer made of a nitride-based semiconductor including a light-emitting layer and having an emitting-side cavity facet and a reflecting-side cavity facet, and a facet coating film formed on the emitting-side cavity facet, while the facet coating film has a first dielectric film made of aluminum nitride formed in contact with the emitting-side cavity facet, a second dielectric film made of aluminum oxynitride formed on a side of the first dielectric film opposite to the emitting-side cavity facet, a third dielectric film made of aluminum oxide formed on a side of the second dielectric film opposite to the first dielectric film, a fourth dielectric film made of aluminum oxynitride formed on a side of the third dielectric film opposite to the second dielectric film, and a fifth dielectric film made of aluminum oxide formed on a side of the fourth dielectric film opposite to the third dielectric film.

In the present invention, the emitting-side cavity facet and the reflecting-side cavity facet are a pair of cavity facets formed on end portions of the nitride-based semiconductor laser element, and distinguished from each other by the relation between intensity levels of laser beams emitted from the cavity facets respectively. In other words, the emitting-side cavity facet has relatively high laser beam intensity, and the reflecting-side cavity facet has relatively low laser beam intensity.

In the nitride-based semiconductor laser element according to the first aspect of the present invention, as hereinabove described, the second dielectric film and the fourth dielectric film made of aluminum oxynitride are formed between the first dielectric film and the third and fifth dielectric films made of aluminum oxide, whereby oxygen in aluminum oxide hardly desorbs and hardly diffuses into the remaining dielectric films. Thus, alteration of the dielectric films can be so reduced that the dielectric films can be inhibited from separating from the emitting-side cavity facet, and change in reflectance of the facet coating film can be suppressed.

As hereinabove described, the second dielectric film made of aluminum oxynitride, the third dielectric film made of aluminum oxide, the fourth dielectric film made of aluminum oxynitride and the fifth dielectric film made of aluminum oxide are successively stacked on the side of the first dielectric film made of aluminum nitride opposite to the emitting-side cavity facet, and these dielectric films contain aluminum in common. Thus, adhesiveness between the dielectric films in the facet coating film is increased, and the facet coating film can be inhibited from separation.

As hereinabove described, the facet coating film has a multilayer film structure so that the thicknesses of the dielectric films can be reduced, whereby stress on the dielectric films can be reduced. Thus, stress on the overall facet coating film can be reduced, whereby the facet coating film can be inhibited from separation.

Consequently, fluctuation in the reflectance of the facet coating film on the emitting-side cavity facet can be suppressed, whereby stability of the nitride-based semiconductor laser element can be improved.

In the aforementioned nitride-based semiconductor laser element according to the first aspect, the first dielectric film is preferably formed by a polycrystalline film of the aluminum nitride. According to this structure, the adhesiveness between the emitting-side cavity facet and the first dielectric film in contact with the emitting-side cavity facet can be increased in the facet coating film.

In this case, the semiconductor element layer including the light-emitting layer preferably has a principal surface consisting of an approximately (0001) plane of the nitride-based semiconductor, and the crystal structure of the polycrystalline film made of the aluminum nitride is preferably oriented along an approximately [0001] direction of the light-emitting layer. According to this structure, the crystal structures of the first dielectric film and the light-emitting layer are aligned approximately in the same direction, whereby the adhesiveness between the emitting-side cavity facet (semiconductor element layer) and the first dielectric film can be reliably improved. Thus, the first dielectric film, so close to the light-emitting layer that the same is easily altered due to concentration of heat energy or light energy, can be inhibited from separating from the emitting-side cavity facet.

In the aforementioned nitride-based semiconductor laser element according to the first aspect, the second dielectric film is preferably formed by a polycrystalline film of the aluminum oxynitride. According to this structure, the adhesiveness between the second dielectric film and other dielectric films adjacent thereto can be improved.

In this case, the semiconductor element layer including the light-emitting layer preferably has a principal surface consisting of an approximately (0001) plane of the nitride-based semiconductor, and the crystal structure of the polycrystalline film made of the aluminum oxynitride is preferably oriented along an approximately [0001] direction of the light-emitting layer. According to this structure, the crystal structures of the second dielectric film and the light-emitting layer are aligned approximately in the same direction, whereby the adhesiveness between the first dielectric film and the second dielectric film can be increased to some extent even if another dielectric film is interposed between the second dielectric film and the emitting-side cavity facet. Thus, the second dielectric film, so close to the light-emitting layer that the same is easily altered due to concentration of heat energy or light energy, can be inhibited from separating from the first dielectric film or the like.

In the aforementioned nitride-based semiconductor laser element according to the first aspect, at least either the third dielectric film or the fifth dielectric film is preferably formed by an amorphous film of aluminum oxide. According to this structure, the amorphous film can properly relax the stress on the overall facet coating film having the multilayer film structure of the first, second, third, fourth and fifth dielectric films.

In the aforementioned nitride-based semiconductor laser element according to the first aspect, the thickness of at least either the first dielectric film or the second dielectric film is preferably smaller than the thickness of at least any of the third dielectric film, the fourth dielectric film and the fifth dielectric film. According to this structure, stress on at least either the first dielectric film or the second dielectric film close to the emitting-side cavity facet can be relatively reduced as compared with stress on at least any of the third dielectric film, the fourth dielectric film and the fifth dielectric film. Thus, either the first dielectric film or the second dielectric film, easily altered due to concentration of heat energy or light energy, can be inhibited from separating from each other in the facet coating film.

In the aforementioned structure in which the thickness of at least either the first dielectric film or the second dielectric film is smaller than the thickness of at least any of the third dielectric film, the fourth dielectric film and the fifth dielectric film, the thickness of each of the first dielectric film and the second dielectric film is preferably smaller than the thickness of each of the third dielectric film, the fourth dielectric film and the fifth dielectric film. According to this structure, stress on the first and second dielectric films close to the emitting-side cavity facet can be relatively reduced as compared with stress on all of the third dielectric film, the fourth dielectric film and the fifth dielectric film. Thus, the first and second dielectric films can be reliably inhibited from separation in the facet coating film.

In this case, the thickness of the second dielectric film is preferably in excess of the thickness of the first dielectric film. According to this structure, the thickness of the first dielectric film can be set below those of the remaining dielectric films, whereby stress on the first dielectric film, made of the aluminum nitride, receiving relatively higher stress than the remaining dielectric films can be reduced. Thus, the adhesiveness between the first and second dielectric films is particularly improved, whereby the facet coating film can be inhibited from separation.

In the aforementioned nitride-based semiconductor laser element according to the first aspect, the second dielectric film and the fourth dielectric film made of the aluminum oxynitride are preferably expressed as AlOxNy (where 0≦x<1.5 and 0<y<1), and preferably satisfy the relation x<y in the AlOxNy. According to this structure, both of the quantity of oxygen contained in the second dielectric film and diffused into the first dielectric film and the quantity of oxygen contained in the fourth dielectric film and diffused into the third dielectric film can be reduced. Thus, oxygen is inhibited from diffusing into the semiconductor element layer through the first dielectric film, whereby the emitting-side cavity facet can be prevented from catastrophic optical damage (COD).

In the aforementioned nitride-based semiconductor laser element according to the first aspect, at least two of the first dielectric film, the second dielectric film, the third dielectric film, the fourth dielectric film and the fifth dielectric film are preferably in contact with each other. According to this structure, no other dielectric film is interposed between the two dielectric films in contact with each other, whereby the thickness of the facet coating film having the multilayer film structure can be minimized. Thus, stress on the overall facet coating film can be further reduced.

In this case, the second dielectric film is preferably in contact with a surface of the first dielectric film opposite to the emitting-side cavity facet, the third dielectric film is preferably in contact with a surface of the second dielectric film opposite to the first dielectric film, the fourth dielectric film is preferably in contact with a surface of the third dielectric film opposite to the second dielectric film, and the fifth dielectric film is preferably in contact with a surface of the fourth dielectric film opposite to the third dielectric film. According to this structure, the adhesiveness between the dielectric films is so improved that the facet coating film can be reliably inhibited from separating from the emitting-side cavity facet.

In the aforementioned nitride-based semiconductor laser element according to the first aspect, the facet coating film preferably further has a sixth dielectric film made of aluminum oxynitride formed on a side of the fifth dielectric film opposite to the fourth dielectric film and a seventh dielectric film made of aluminum oxide formed on a side of the sixth dielectric film opposite to the fifth dielectric film. According to this structure, a facet coating film whose reflectance can be more easily controlled can be formed while inhibiting the same from separating from the emitting-side cavity facet.

In this case, the thickness of at least either the first dielectric film or the second dielectric film is preferably smaller than the thickness of at least either the sixth dielectric film or the seventh dielectric film. According to this structure, stress on at least either the first dielectric film or the second dielectric film close to the emitting-side cavity facet can be relatively reduced as compared with stress on at least either the sixth dielectric film or the seventh dielectric film. Thus, the first and second dielectric films, easily altered due to concentration of heat energy or light energy, can be inhibited from separation even if the facet coating film further includes the sixth and seventh dielectric films.

In the aforementioned structure having the facet coating film further including the sixth and seventh dielectric films, the thickness of each of the first dielectric film and the second dielectric film is preferably smaller than the thickness of each of the third dielectric film, the fourth dielectric film, the fifth dielectric film, the sixth dielectric film and the seventh dielectric film. According to this structure, stress on the first and second dielectric films close to the emitting-side cavity facet can be relatively reduced. Thus, the first and second dielectric films, easily altered due to concentration of heat energy or light energy, can be easily inhibited from separating from the emitting-side cavity facet.

In the aforementioned structure having the facet coating film further including the sixth and seventh dielectric films, the thickness of the seventh dielectric film is preferably larger than the thickness of the sixth dielectric film. According to this structure, stress, relatively larger than that on the seventh dielectric film, on the sixth dielectric film made of aluminum nitride can be so reduced that the adhesiveness between the sixth and seventh dielectric films can be improved. Thus, the sixth and seventh dielectric films can be inhibited from separating from each other in the facet coating film.

In the aforementioned structure having the facet coating film further including the sixth and seventh dielectric films, the sixth dielectric film made of the aluminum oxynitride is preferably expressed as AlOxNy (where 0≦x<1.5 and 0<y<1), and preferably satisfies the relation x<y in the AlOxNy. According to this structure, the quantity of oxygen contained in the sixth dielectric film and diffused into the fifth dielectric film can be easily reduced.

In the aforementioned structure having the facet coating film further including the sixth and seventh dielectric films, the second dielectric film is preferably in contact with a surface of the first dielectric film opposite to the emitting-side cavity facet, the third dielectric film is preferably in contact with a surface of the second dielectric film opposite to the first dielectric film, the fourth dielectric film is preferably in contact with a surface of the third dielectric film opposite to the second dielectric film, the fifth dielectric film is preferably in contact with a surface of the fourth dielectric film opposite to the third dielectric film, the sixth dielectric film is preferably in contact with a surface of the fifth dielectric film opposite to the fourth dielectric film, and the seventh dielectric film is preferably in contact with a surface of the sixth dielectric film opposite to the fifth dielectric film. According to this structure, the adhesiveness between the dielectric films is so improved that the facet coating film can be reliably inhibited from separating from the emitting-side cavity facet.

In the aforementioned nitride-based semiconductor laser element according to the first aspect, the semiconductor element layer preferably has a principal surface consisting of an approximately (0001) plane of the nitride-based semiconductor, the light-emitting layer preferably includes an active layer, the nitride-based semiconductor laser element preferably further includes a ridge portion for forming a waveguide on the active layer of the semiconductor element layer, and the ridge portion preferably extends along an approximately [1-100] direction of the semiconductor element layer. According to this structure, the facet coating film according to the present invention can be easily formed on the emitting-side cavity facet consisting of an approximately (1-100) plane.

An optical apparatus according to a second aspect of the present invention includes a nitride-based semiconductor laser element and an optical system controlling light emitted from the nitride-based semiconductor laser element, while the nitride-based semiconductor laser element includes a semiconductor element layer made of a nitride-based semiconductor including a light-emitting layer and having an emitting-side cavity facet and a reflecting-side cavity facet, and a facet coating film formed on the emitting-side cavity facet, and the facet coating film has a first dielectric film made of aluminum nitride formed in contact with the emitting-side cavity facet, a second dielectric film made of aluminum oxynitride formed on a side of the first dielectric film opposite to the emitting-side cavity facet, a third dielectric film made of aluminum oxide formed on a side of the second dielectric film opposite to the first dielectric film, a fourth dielectric film made of aluminum oxynitride formed on a side of the third dielectric film opposite to the second dielectric film, and a fifth dielectric film made of aluminum oxide formed on a side of the fourth dielectric film opposite to the third dielectric film.

In the optical apparatus according to the second aspect of the present invention, the nitride-based semiconductor laser element loaded on the optical apparatus has the aforementioned structure, whereby separation of the facet coating film is suppressed, and stability of the nitride-based semiconductor laser element can be improved. Consequently, stability of the optical apparatus can be improved by employing this nitride-based semiconductor laser element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a nitride-based semiconductor laser element according to a first embodiment of the present invention in a direction parallel to a light-emitting direction (direction L);

FIG. 2 is a sectional view of the nitride-based semiconductor laser element according to the first embodiment of the present invention in a direction orthogonal to the light-emitting direction;

FIG. 3 is a sectional view of a nitride-based semiconductor laser element according to a second embodiment of the present invention along a cavity direction (direction L); and

FIG. 4 is a schematic diagram showing the structure of an optical pickup apparatus including a three-wavelength semiconductor laser device according to a third embodiment of the present invention.

### DESCRIPTION OF THE PREFERRED EMBODIMENTS

Embodiments of the present invention are now described with reference to the drawings.

### First Embodiment

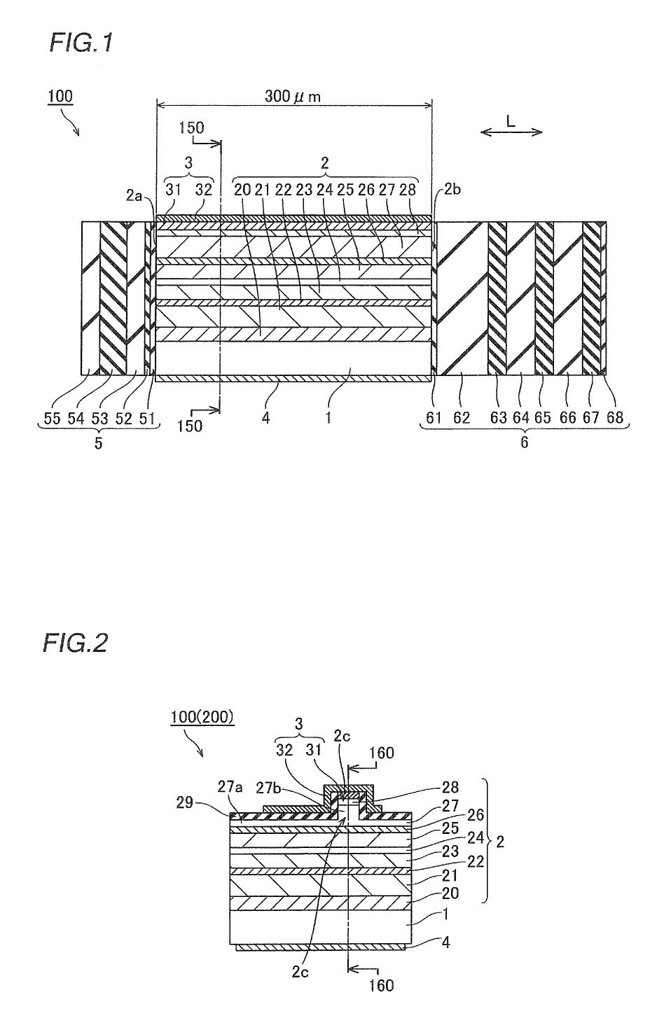

A nitride-based semiconductor laser element 100 according to a first embodiment of the present invention has a lasing wavelength of about 405 nm, and includes a semiconductor element layer 2 made of a nitride-based semiconductor formed on the upper surface (approximately (0001) Ga plane) of a substrate 1 made of n-type GaN, a p-side electrode 3 formed on the semiconductor element layer 2 and an n-side electrode 4 formed on the lower surface (approximately (0001) N plane) of the substrate 1, as shown in FIGS. 1 and 2. The semiconductor element layer 2 is provided with a pair of cavity facets, i.e., an emitting-side cavity facet 2a and a reflecting-side cavity facet 2b, orthogonal to a light-emitting direction (direction L (approximately [1-100] direction)). In other words, the pair of cavity facets 2a and 2b consist of approximately (1-100) planes. FIG. 1 shows a section, taken along the line 160-160 in FIG. 2, of the nitride-based semiconductor laser element 100 in a direction parallel to the light-emitting direction (direction L). FIG. 2 shows another section, taken along the line 150-150 in FIG. 1, of the nitride-based semiconductor laser element 100 orthogonal to the light-emitting direction.

The distance (cavity length) between the emitting-side cavity facet 2a and the reflecting-side cavity facet 2b is about 300 μm, while a first facet coating film 5 and a second facet coating film 6 each formed by stacking a plurality of dielectric films are formed on the emitting-side cavity facet 2a and the reflecting-side cavity facet 2b respectively. The first facet coating film 5 is an example of the “facet coating film” in the present invention.

The substrate 1 has a thickness of about 100 μm, and is doped with oxygen having a carrier concentration of about 5×10¹⁸ cm⁻³. The semiconductor element layer 2 formed on the upper surface of the substrate 1 is constituted of an n-type buffer layer 20, an n-type cladding layer 21, an n-type carrier blocking layer 22, an n-side light guide layer 23, an active layer 24, a p-side light guide layer 25, a cap layer 26, a p-type cladding layer 27 and a p-side contact layer 28 successively stacked from the side of the substrate 1. The n-type carrier blocking layer 22, the n-side light guide layer 23, the active layer 24, the p-side light guide layer 25 and the cap layer 26 constitute the “light-emitting layer” in the present invention.

The n-type buffer layer 20, the n-type cladding layer 21, the n-type carrier blocking layer 22 and the n-side light guide layer 23 are made of n-type GaN having a thickness of about 100 nm, n-type Al_{0.07}Ga_{0.93}N having a thickness of about 2 μm, n-type Al_{0.16}Ga_{0.84}N having a thickness of about 5 nm and undoped GaN having a thickness of about 100 nm respectively. Each of the n-type layers 20 to 22 is doped with Ge by about 5×10¹⁸ cm⁻³, and has a carrier concentration of about 5×10¹⁸ cm⁻³.

The active layer 24 has an MQW structure obtained by alternately stacking four barrier layers each made of undoped In_{0.02}Ga_{0.98}N having a thickness of about 20 nm and three well layers each made of undoped In_{0.1}Ga_{0.9}N having a thickness of about 3 nm.

The p-side light guide layer 25, the cap layer 26 and the p-side contact layer 28 are made of undoped GaN having a thickness of about 100 nm, undoped Al_{0.16}Ga_{0.84}N having a thickness of about 20 nm and undoped In_{0.02}Ga_{0.98}N having a thickness of about 10 nm respectively.

The p-type cladding layer 27 is made of p-type Al_{0.07}Ga_{0.93}N, doped with Mg by about 4×10¹⁹ cm⁻³, having a carrier concentration of about 5×10¹⁷ cm⁻³. The p-type cladding layer 27 includes a planar portion 27a having a thickness of about 80 nm and a projecting portion 27b, having a height of about 320 nm and a width of about 1.5 μm, projecting from the planar portion 27a. The projecting portion 27b is provided in the form of a stripe, and extends in the direction L perpendicular to the emitting-side cavity facet 2a and the reflecting-side cavity facet 2b. The p-side contact layer 28 is formed only on the projecting portion 27b, so that a ridge portion 2c is formed by the projecting portion 27b of the p-type cladding layer 27 and the p-side contact layer 28. As shown in FIG. 2, the ridge portion 2c is formed on a position deviating from the center of the nitride-based semiconductor laser element 100 toward one side surface thereof, and the nitride-based semiconductor laser element 100 has a horizontally asymmetrical sectional shape. A current narrowing layer 29, having a thickness of about 250 nm, made of SiO₂ is formed on the upper surface of the planar portion 27a of the p-type cladding layer 27 and the side surfaces of the ridge portion 2c.

The p-side electrode 3 consisting of a p-side ohmic electrode 31 formed on the p-side contact layer 28 exposed from the current narrowing layer 29 and a p-side pad electrode 32 formed on the p-side ohmic electrode 31 and the current narrowing layer 29 is formed on the semiconductor element layer 2. The p-side ohmic electrode 31 consists of a Pt layer having a thickness of about 10 nm and a Pd layer having a thickness of about 100 nm successively formed from the side of the p-side contact layer 28.

The p-side pad electrode 32 consists of a Ti layer having a thickness of about 100 nm, a Pd layer having a thickness of about 100 nm and an Au layer having a thickness of about 3 μm successively formed from the side of the p-side ohmic electrode 31 and the current narrowing layer 29. A wire bonding portion (not shown) of the p-side pad electrode 32 is formed above the planar portion 27a of the p-type cladding layer 27. The n-side electrode 4 consists of an Al layer having a thickness of about 10 nm, a Pd layer having a thickness of about 20 nm and an Au layer having a thickness of about 300 nm successively formed on the lower surface of the substrate 1 from the side of the substrate 1.

The first facet coating film 5 consists of an AlN layer 51 having a thickness of about 10 nm, an AlOxNy layer 52 (0≦x<1.5, 0<y<1 and x<y) having a thickness of about 10 nm, an Al₂O₃ layer 53 having a thickness of about 30 nm, an AlOxNy layer 54 (0≦x<1.5, 0<y<1 and x<y) having a thickness of about 40 nm and an Al₂O₃ layer 55 having a thickness of about 28 nm successively formed from the side of the emitting-side cavity facet 2a. Referring to the AlOxNy layers 52 and 54, x and y represent atomic ratios of oxygen and nitrogen constituting oxynitride films respectively.

In other words, the AlN layer 51 is formed in contact with the emitting-side cavity facet 2a. The AlOxNy layer 52 is formed in contact with a surface of the AlN layer 51 opposite to the emitting-side cavity facet 2a. The Al₂O₃ layer 53 is formed in contact with a surface of the AlOxNy layer 52 opposite to the AlN layer 51. The AlOxNy layer 54 is formed in contact with a surface of the Al₂O₃ layer 53 opposite to the AlOxNy layer 52. The Al₂O₃ layer 55 is formed in contact with a surface of the AlOxNy layer 54 opposite to the Al₂O₃ layer 53. The AlN layer 51, the AlOxNy layer 52, the Al₂O₃ layer 53, the AlOxNy layer 54 and the Al₂O₃ layer 55 are examples of the “first dielectric film made of aluminum nitride”, the “second dielectric film made of aluminum oxynitride”, the “third dielectric film made of aluminum oxide”, the “fourth dielectric film made of aluminum oxynitride” and the “fifth dielectric film made of aluminum oxide” in the present invention respectively.

Both of the AlN layer 51 and the AlOxNy layer 52 are constituted of polycrystalline films oriented in the direction, similarly to the aforementioned light-emitting layer. Both of the Al₂O₃ layers 53 and 55 are constituted of amorphous films.

The refractive indices of the AlN layer 51, the AlOxNy layers 52 and 54 and the Al₂O₃ layers 53 and 55 are about 2.051, about 1.933 and about 1.649 (measured wavelength: λ=632.8 nm) respectively, and the reflectance of the first facet coating film 5 is set to about 26% (measured wavelength: λ=405 nm) due to the aforementioned structure.

The second facet coating film 6 consists of an AlN layer 61 having a thickness of about 10 nm, an Al₂O₃ layer 62 having a thickness of about 180 nm, a ZrO₂ layer 63 having a thickness of about 45 nm, an Al₂O₃ layer 64 having a thickness of about 62 nm, a ZrO₂ layer 65 having a thickness of about 45 nm, an Al₂O₃ layer 66 having a thickness of about 62 nm, a ZrO₂ layer 67 having a thickness of about 45 nm and an AlN layer 68 having a thickness of about 10 nm successively formed from the side of the reflecting-side cavity facet 2b.

In other words, the AlN layer 61 is in contact with the reflecting-side cavity facet 2b. The Al₂O₃ layer 62 is formed in contact with a surface of the AlN layer 61 opposite to the reflecting-side cavity facet 2b. The ZrO₂ layer 63 is formed in contact with a surface of the Al₂O₃ layer 62 opposite to the AlN layer 61. The Al₂O₃ layer 64 is formed in contact with a surface of the ZrO₂ layer 63 opposite to the Al₂O₃ layer 62. The ZrO₂ layer 65 is formed in contact with a surface of the Al₂O₃ layer 64 opposite to the ZrO₂ layer 63. The Al₂O₃ layer 66 is formed in contact with a surface of the ZrO₂ layer 65 opposite to the Al₂O₃ layer 64. The ZrO₂ layer 67 is formed in contact with a surface of the Al₂O₃ layer 66 opposite to the ZrO₂ layer 65. The AlN layer 68 is formed in contact with a surface of the ZrO₂ layer 67 opposite to the Al₂O₃ layer 66.

The refractive indices of the AlN layers 61 and 68, the Al₂O₃ layers 62, 64 and 66 and the ZrO₂ layers 63, 65 and 67 are about 2.051, about 1.649 and about 2.150 respectively (measured wavelength: λ=632.8 nm). The reflectance of the second facet coating film 6 is set to about 74% (measured wavelength: λ=405 nm) due to this structure.

The reflectance of the first facet coating film 5 is set smaller than that of the second facet coating film 6 due to the aforementioned structures, and hence the nitride-based semiconductor laser element 100 is so formed that the intensity of a laser beam emitted from the side of the first facet coating film 5 is higher than that of a laser beam emitted from the side of the second facet coating film 6.

In the nitride-based semiconductor laser element 100, as hereinabove described, the AlOxNy layers 52 and 54 are formed between the AlN layer 51 and the Al₂O₃ layers 53 and 55 respectively, whereby oxygen in the Al₂O₃ layers 53 and 55 hardly desorbs and hardly diffuses into the remaining dielectric films. Thus, alteration of these layers can be reduced, whereby the first facet coating film 5 can be inhibited from separating from the emitting-side cavity facet 2a. Further, change in the reflectance of the first facet coating film 5 can be suppressed.

The AlOxNy layer 52, the Al₂O₃ layer 53, the AlOxNy layer 54 and the Al₂O₃ layer 55 are successively stacked on the surface of the AlN layer 51 in this order in contact with each other, and these layers contain aluminum in common. Thus, adhesiveness between the layers is increased, and the first facet coating film 5 can be inhibited from separating from the emitting-side cavity facet 2a.

The first facet coating film 5 is so brought into the multilayer film structure that the thicknesses of the layers can be reduced, whereby stress on the layers can be reduced. Thus, stress on the overall first facet coating film 5 can be reduced, whereby the first facet coating film 5 can be inhibited from separating from the emitting-side cavity facet 2a.

In the nitride-based semiconductor laser element 100, the AlN layer 51 is formed in contact with the emitting-side cavity facet 2a, whereby oxygen can be inhibited from diffusing from the external atmosphere or the Al₂O₃ layers 53 and 55 into the semiconductor element layer 2 made of the nitride-based semiconductor. Thus, a non-radiative recombination level causing absorption of the laser beam or heat generation is hardly formed in the emitting-side cavity facet 2a, whereby the first facet coating film 5 can be prevented from catastrophic optical damage (COD).

Consequently, fluctuation in the reflectance of the first facet coating film 5 on the emitting-side cavity facet 2a can be suppressed, whereby stability of the nitride-based semiconductor laser element 100 can be improved.

The thickness of each of the AlN layer 51 and the AlOxNy layer 52 is smaller than the thickness of each of the dielectric films of the Al₂O₃ layer 53, the AlOxNy layer 54 and the Al₂O₃ layer 55. Thus, stress on the AlN layer 51 and the AlOxNy layer 52 close to the emitting-side cavity facet 2a can be relatively reduced. Therefore, the AlN layer 51 and the AlOxNy layer 52, easily altered due to concentration of heat energy or light energy, can be inhibited from separating from the emitting-side cavity facet 2a.

The thickness of the AlOxNy layer 52 is in excess of the thickness of the AlN layer 51. In other words, the thickness of the AlN layer 51 is set below those of the remaining dielectric films, whereby stress on the AlN layer 51 receiving relatively higher stress than the remaining dielectric films can be reduced. Thus, the adhesiveness between the AlN layer 51 and the AlOxNy layer 52 is particularly improved, whereby the AlN layer 51 and the AlOxNy layer 52 can be inhibited from separating from each other.

The reflectance of the first facet coating film 5 with respect to the lasing wavelength (405 nm) of the laser beam is set to the value of at least 25%, whereby the emitting-side cavity facet 2a can be prevented from concentration of heat energy or light energy. Thus, the layers of the first facet coating film 5 are hardly altered, and separation from the emitting-side cavity facet 2a can be suppressed.

In the AlOxNy layers 52 and 54, the atomic ratio y of nitrogen is larger than the atomic ratio x of oxygen. Thus, both of the quantities of oxygen contained in the AlOxNy layers 52 and 54 and diffused into the AlN layer 51 and the Al₂O₃ layer 53 respectively can be reduced.

Consequently, oxygen can be inhibited from diffusing into the semiconductor element layer 2 through the AlN layer 51, whereby the emitting-side cavity facet 2a can be prevented from catastrophic optical damage (COD).

In the nitride-based semiconductor laser element 100, the distance between the emitting-side cavity facet 2a and the reflecting-side cavity facet 2b is set to a value of not more than 300 μm, and hence the temperature of the nitride-based semiconductor laser element 100 easily rises. While a facet coating film on a light-emitting side is easily altered in a nitride-based semiconductor laser element having a small cavity length, the nitride-based semiconductor laser element 100 has the first facet coating film 5 having the aforementioned structure, whereby the first facet coating film 5 can be effectively inhibited from alteration and separation.

Both of the AlN layer 51 and the AlOxNy layer 52 are constituted of the polycrystalline films (dielectric films) oriented in the [0001] direction identically to the aforementioned light-emitting layer, whereby the adhesiveness between the layers can be improved. Thus, the AlN layer 51 and the AlOxNy layer 52 close to the aforementioned light-emitting layer and easily altered due to concentration of heat energy or light energy can be inhibited from separation.

Both of the Al₂O₃ layers 53 and 55 are constituted of the amorphous films, whereby stress enlarged due to the polycrystalline films of the AlN layer 51 and the AlOxNy layer 52 can be relaxed.

In the nitride-based semiconductor laser element 100, the ridge portion 2c extends along the approximately [1-100] direction of the semiconductor element layer 2. Thus, the “facet coating film” in the present invention can be easily formed with respect to the emitting-side cavity facet 2a consisting of the approximately (1-100) plane.

### Second Embodiment

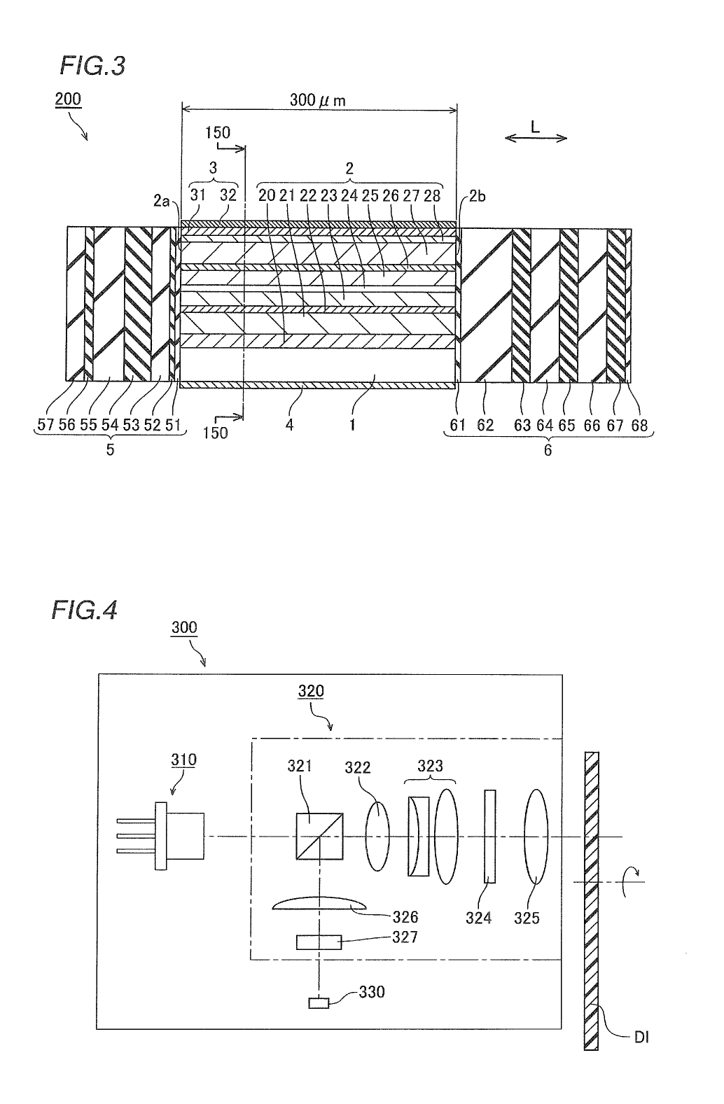

The structure of a nitride-based semiconductor laser element 200 according to a second embodiment of the present invention is described with reference to FIG. 3. FIG. 3 shows a section of the nitride-based semiconductor laser element 200 parallel to a laser beam emitting direction (direction L).

In the nitride-based semiconductor laser element 200, the structure of a first facet coating film 5 on an emitting-side cavity facet 2a is different from that of the first facet coating film 5 of the nitride-based semiconductor laser element 100 in a point that an Al₂O₃ layer 53, an AlOxNy layer 54 and an Al₂O₃ layer 55 have thicknesses of about 33 nm, about 56 nm and about 65 nm respectively. An AlOxNy layer 56 (0≦x<1.5, 0<y<1 and x<y) having a thickness of about 17 nm is formed in contact with a surface of the Al₂O₃ layer 55 opposite to the AlOxNy layer 54, while an Al₂O₃ layer 57 having a thickness of about 38 nm is formed in contact with a surface of the AlOxNy layer 56 opposite to the Al₂O₃ layer 55. Referring to the AlOxNy layer 56, x and y represent atomic ratios of oxygen and nitrogen constituting an oxynitride film respectively. The AlOxNy layer 56 and the Al₂O₃ layer 57 are examples of the “sixth dielectric film made of aluminum oxynitride” and the “seventh dielectric film made of aluminum oxide” in the present invention respectively.

The refractive indices of the AlOxNy layer 56 and the Al₂O₃ layer 57 are about 1.933 and about 1.649 respectively (measured wavelength: λ=632.8 nm), and the reflectance of the first facet coating film 5 of the nitride-based semiconductor laser element 200 is set to about 35% (measured wavelength: λ=405 nm) due to the aforementioned structure. The remaining structure of the nitride-based semiconductor laser element 200 is similar to that of the nitride-based semiconductor laser element 100.

In the nitride-based semiconductor laser element 200, the first facet coating film 5 further includes the AlOxNy layer 56 in contact with the Al₂O₃ layer 55 and the Al₂O₃ layer 57 in contact with the AlOxNy layer 56, as compared with the structure of the first facet coating film 5 of the nitride-based semiconductor laser element 100. Thus, even if the first facet coating film 5 has a larger number of layers, the adhesiveness between the layers from the AlN layer 51 up to the Al₂O₃ layer 57 is so improved that a first facet coating film 5 whose reflectance can be more easily controlled can be constituted while suppressing separation from an emitting-side cavity facet 2a.

In the AlOxNy layer 56, the atomic ratio y of nitrogen is larger than the atomic ratio x of oxygen. Thus, the quantity of oxygen contained in the AlOxNy layer 56 and diffused into the Al₂O₃ layer 55 can be easily reduced.

The thicknesses of the AlN layer 51 and the AlOxNy layer 52 are smaller than the thicknesses of the Al₂O₃ layer 53, the AlOxNy layer 54, the Al₂O₃ layer 55, the AlOxNy layer 56 and the Al₂O₃ layer 57. Thus, stress on the AlN layer 51 and the AlOxNy layer 52 close to the emitting-side cavity facet 2a can be relatively reduced, whereby the AlN layer 51 and the AlOxNy layer 52, easily altered due to concentration of heat energy or light energy, can be inhibited from separation. The remaining effects of the second embodiment are similar to those of the aforementioned first embodiment.

### Third Embodiment

The structure of an optical pickup apparatus 300 according to a third embodiment of the present invention is now described with reference to FIG. 4. The optical pickup apparatus 300 is an example of the “optical apparatus” in the present invention.

The optical pickup apparatus 300 includes a three-wavelength semiconductor laser device 310, an optical system 320 adjusting laser beams emitted from the three-wavelength semiconductor laser device 310 and a light detection portion 330 receiving the laser beams, as shown in FIG. 4.

The three-wavelength semiconductor laser device 310 is loaded with the aforementioned nitride-based semiconductor laser element 200 and a red/infrared two-wavelength semiconductor laser element (not shown) emitting a red laser beam having a wavelength of about 650 nm and an infrared laser beam having a wavelength of about 780 nm, and can separately emit laser beams of three wavelengths.

The optical system 320 has a polarized beam splitter (PBS) 321, a collimator lens 322, a beam expander 323, a λ/4 plate 324, an objective lens 325, a cylindrical lens 326 and an optical axis correction device 327. The PBS 321 totally transmits the laser beams emitted from the three-wavelength semiconductor laser device 310, and totally reflects the laser beams fed back from an optical disk DI. The collimator lens 322 converts the laser beams emitted from the three-wavelength semiconductor laser device 310 and transmitted through the PBS 321 to parallel beams. The beam expander 323 is constituted of a concave lens, a convex lens and an actuator (not shown). The actuator has a function of correcting wave front states of the laser beams emitted from the three-wavelength semiconductor laser device 310 by varying the distance between the concave lens and the convex lens in response to servo signals from a servo circuit described later.

The λ/4 plate 324 converts the laser beams of linear polarization, converted to substantially parallel beams by the collimator lens 322, to those of circular polarization. Further, the λ/4 plate 324 converts the laser beams of circular polarization, fed back from the optical disk DI, to those of linear polarization. The direction of the linear polarization in this case is orthogonal to the direction of the linear polarization of the laser beams emitted from the three-wavelength semiconductor laser device 310. Thus, the PBS 321 substantially totally reflects the laser beams fed back from the optical disk DI. The objective lens 325 converges the laser beams transmitted through the λ/4 plate 324 on the surface (recording layer) of the optical disk DI. The objective lens 325 is rendered movable with an objective lens actuator (not shown) in a focusing direction, a tracking direction and a tilting direction in response to the servo signals (a tracking servo signal, a focusing servo signal and a tilting servo signal) from the servo circuit described later.

The cylindrical lens 326, the optical axis correction device 327 and the light detection portion 330 are arranged to be along the optical axes of the laser beams totally reflected by the PBS 321. The cylindrical lens 326 provides astigmatic action to the incident laser beams. The optical axis correction device 327 is constituted of a diffraction grating, and so arranged that spots of zero-order diffracted beams of the violet, red and infrared laser beams transmitted through the cylindrical lens 326 coincide with each other on a detection region of the light detection portion 330 described later.

The light detection portion 330 outputs a playback signal on the basis of intensity distribution of the received laser beams. The light detection portion 330 has the detection region of a prescribed pattern so that a focusing error signal, a tracking error signal and a tilting error signal are obtained along with the playback signal. The optical pickup apparatus 300 including the three-wavelength semiconductor laser device 310 is constituted in the aforementioned manner.

The laser beams emitted from the three-wavelength semiconductor laser device 310 are adjusted through the PBS 321, the collimator lens 322, the beam expander 323, the λ/4 plate 324, the objective lens 325, the cylindrical lens 326 and the optical axis correction device 327 as described above, and thereafter applied onto the detection region of the light detection portion 330.

In order to play back information recorded in the optical disk DI, the laser beams are applied to the recording layer of the optical disk DI while the laser beams emitted from the nitride-based semiconductor laser element 200 and the red/infrared two-wavelength semiconductor laser element selected in response to the type of the optical disk DI are controlled to constant power, so that the playback signal output from the light detection portion 330 can be obtained. Further, the actuator of the beam expander 323 and the objective lens actuator driving the objective lens 325 can be feedback-controlled by the focusing error signal, the tracking error signal and the tilting error signal output at the same time.

In order to record information in the optical disk DI, on the other hand, the laser beams are applied to the optical disk DI while power of the laser beams emitted from the nitride-based semiconductor laser element 200 and the red/infrared two-wavelength semiconductor laser element selected in response to the type of the optical disk DI is controlled on the basis of the information to be recorded. Thus, the information can be recorded in the recording layer of the optical disk DI. Further, the actuator of the beam expander 323 and the objective lens actuator driving the objective lens 325 can be feedback-controlled by the focusing error signal, the tracking error signal and the tilting error signal output from the light detection portion 330, similarly to the above.

Thus, information can be recorded in/played back from the optical disk DI with the optical pickup apparatus 300 including the three-wavelength semiconductor laser device 310.

The three-wavelength semiconductor laser device 310 of the optical pickup apparatus 300 includes the aforementioned nitride-based semiconductor laser element 200, whereby stability and reliability can be improved. The remaining effects of the optical pickup apparatus 300 are similar to those of the nitride-based semiconductor laser element 200.

Although the present invention has been described and illustrated in detail, it is clearly understood that the same is by way of illustration and example only and is not to be taken by way of limitation, the spirit and scope of the present invention being limited only by the terms of the appended claims.

For example, while the cavity length of the nitride-based semiconductor laser element is 300 μm in each of the aforementioned embodiments, the present invention is not restricted to this, but the nitride-based semiconductor laser element may alternatively have a larger cavity length.

While the AlN layer 51 is formed by the polycrystalline film oriented in the [0001] direction identically to the light-emitting layer in each of the aforementioned embodiments, the present invention is not restricted to this, but the AlN layer 51 may alternatively be oriented in another direction, or may further alternatively be formed by an amorphous film or a microcrystalline film.

While the Al₂O₃ layers 53 and 55 are constituted of the amorphous films in each of the aforementioned embodiments, the present invention is not restricted to this, but the Al₂O₃ layers 53 and 55 may alternatively be constituted of polycrystalline films or microcrystalline films.

While the semiconductor element layer 2 is formed on the principal surface of the n-type (0001) plane GaN substrate 1 so that the ridge portion 2c extends in the [1-100] direction in each of the aforementioned embodiments, the present invention is not restricted to this, but a nitride-based semiconductor laser element may alternatively be formed by forming a semiconductor element layer on an n-type GaN substrate having a principal surface consisting of plane orientation of an a plane ((11-20) plane) or an m plane ((1-100) plane). Particularly in a case of forming a semiconductor element layer on a principal surface consisting of a non-polar plane such as an a plane or an m plane, a ridge portion extending along a [0001] direction is formed on the semiconductor element layer, and c planes ((0001) and (000-1) planes) of the semiconductor element layer can be employed as cavity facets. The semiconductor element layer is so crystal-grown on the a plane or the m plane of the n-type GaN substrate that a piezoelectric field generated in an active layer can be more reduced, whereby a nitride-based semiconductor laser element more improved in luminous efficiency can be obtained. When the semiconductor element layer is formed on the principal surface consisting of the aforementioned c plane, it is also possible to form a ridge portion extending along a [11-20] direction on the semiconductor element layer, for example, and a (11-20) plane and a (−1-120) plane of the semiconductor element layer can be employed as cavity facets in this case. When the semiconductor element layer is formed on the principal surface consisting of the aforementioned c plane, further, it is also possible to form a ridge portion extending along a [1-100] direction on the semiconductor element layer, and a (1-100) plane and a (−1100) plane of the semiconductor element layer can be employed as cavity facets in this case.

While the optical pickup apparatus including the three-wavelength semiconductor laser device 310 is shown in the aforementioned third embodiment, the present invention is not restricted to this, but the optical pickup apparatus may alternatively be loaded with only the nitride-based semiconductor laser element.

While the optical pickup apparatus is shown in the aforementioned third embodiment, the present invention is not restricted to this, but may alternatively be applied to a projector or a display employing an optical pickup loaded with the nitride-based semiconductor laser element according to the present invention or an RGB three-wavelength semiconductor laser device loaded with a red semiconductor laser element and a green semiconductor laser element.

According to the present invention, a multilayer film structure can be formed as to the structure of the second facet coating film 6 by properly selecting dielectric layers made of other materials such as AlOxNy, SiO₂, Hf₂O, Nb₂O₅, Ta₂O₅ and TiO₂.

What is claimed is:

1. A nitride-based semiconductor laser element comprising:
a semiconductor element layer made of a nitride-based semiconductor including a light-emitting layer and having an emitting-side cavity facet and a reflecting-side cavity facet; and
a facet coating film formed on said emitting-side cavity facet, wherein
said facet coating film has a first dielectric film made of aluminum nitride formed in contact with said emitting-side cavity facet, a second dielectric film made of aluminum oxynitride formed on a side of said first dielectric film opposite to said emitting-side cavity facet, a third dielectric film made of aluminum oxide formed on a side of said second dielectric film opposite to said first dielectric film, a fourth dielectric film made of aluminum oxynitride formed on a side of said third dielectric film opposite to said second dielectric film, and a fifth dielectric film made of aluminum oxide formed on a side of said fourth dielectric film opposite to said third dielectric film.

2. The nitride-based semiconductor laser element according to claim 1, wherein
said first dielectric film is formed by a polycrystalline film of said aluminum nitride.

3. The nitride-based semiconductor laser element according to claim 2, wherein
said semiconductor element layer including said light-emitting layer has a principal surface consisting of an approximately (0001) plane of said nitride-based semiconductor, and
the crystal structure of said polycrystalline film made of said aluminum nitride is oriented along an approximately [0001] direction of said light-emitting layer.

4. The nitride-based semiconductor laser element according to claim 1, wherein
said second dielectric film is formed by a polycrystalline film of said aluminum oxynitride.

5. The nitride-based semiconductor laser element according to claim 4, wherein
said semiconductor element layer including said light-emitting layer has a principal surface consisting of an approximately (0001) plane of said nitride-based semiconductor, and
the crystal structure of said polycrystalline film made of said aluminum oxynitride is oriented along an approximately [0001] direction of said light-emitting layer.

6. The nitride-based semiconductor laser element according to claim 1, wherein
at least either said third dielectric film or said fifth dielectric film is formed by an amorphous film of aluminum oxide.

7. The nitride-based semiconductor laser element according to claim 1, wherein
the thickness of at least either said first dielectric film or said second dielectric film is smaller than the thickness of at least any of said third dielectric film, said fourth dielectric film and said fifth dielectric film.

8. The nitride-based semiconductor laser element according to claim 7, wherein
the thickness of each of said first dielectric film and said second dielectric film is smaller than the thickness of each of said third dielectric film, said fourth dielectric film and said fifth dielectric film.

9. The nitride-based semiconductor laser element according to claim 8, wherein
the thickness of said second dielectric film is in excess of the thickness of said first dielectric film.

10. The nitride-based semiconductor laser element according to claim 1, wherein
said second dielectric film and said fourth dielectric film made of said aluminum oxynitride are expressed as AlOxNy (where 0≦x<1.5 and 0<y<1), and
satisfy the relation x<y in said AlOxNy.

11. The nitride-based semiconductor laser element according to claim 1, wherein
at least two of said first dielectric film, said second dielectric film, said third dielectric film, said fourth dielectric film and said fifth dielectric film are in contact with each other.

12. The nitride-based semiconductor laser element according to claim 11, wherein
said second dielectric film is in contact with a surface of said first dielectric film opposite to said emitting-side cavity facet,
said third dielectric film is in contact with a surface of said second dielectric film opposite to said first dielectric film,
said fourth dielectric film is in contact with a surface of said third dielectric film opposite to said second dielectric film, and
said fifth dielectric film is in contact with a surface of said fourth dielectric film opposite to said third dielectric film.

13. The nitride-based semiconductor laser element according to claim 1, wherein
said facet coating film further has a sixth dielectric film made of aluminum oxynitride formed on a side of said fifth dielectric film opposite to said fourth dielectric film and a seventh dielectric film made of aluminum oxide formed on a side of said sixth dielectric film opposite to said fifth dielectric film.

14. The nitride-based semiconductor laser element according to claim 13, wherein
the thickness of at least either said first dielectric film or said second dielectric film is smaller than the thickness of at least either said sixth dielectric film or said seventh dielectric film.

15. The nitride-based semiconductor laser element according to claim 14, wherein
the thickness of each of said first dielectric film and said second dielectric film is smaller than the thickness of each of said third dielectric film, said fourth dielectric film, said fifth dielectric film, said sixth dielectric film and said seventh dielectric film.

16. The nitride-based semiconductor laser element according to claim 13, wherein
the thickness of said seventh dielectric film is larger than the thickness of said sixth dielectric film.

17. The nitride-based semiconductor laser element according to claim 13, wherein
said sixth dielectric film made of said aluminum oxynitride is expressed as AlOxNy (where 0≦x<1.5 and 0<y<1), and
satisfies the relation x<y in said AlOxNy.

18. The nitride-based semiconductor laser element according to claim 13, wherein
said second dielectric film is in contact with a surface of said first dielectric film opposite to said emitting-side cavity facet,
said third dielectric film is in contact with a surface of said second dielectric film opposite to said first dielectric film,
said fourth dielectric film is in contact with a surface of said third dielectric film opposite to said second dielectric film,
said fifth dielectric film is in contact with a surface of said fourth dielectric film opposite to said third dielectric film,
said sixth dielectric film is in contact with a surface of said fifth dielectric film opposite to said fourth dielectric film, and
said seventh dielectric film is in contact with a surface of said sixth dielectric film opposite to said fifth dielectric film.

19. The nitride-based semiconductor laser element according to claim 1, wherein
said semiconductor element layer has a principal surface consisting of an approximately (0001) plane of said nitride-based semiconductor,
said light-emitting layer includes an active layer,
the nitride-based semiconductor laser element further comprises a ridge portion for forming a waveguide on said active layer of said semiconductor element layer, and
said ridge portion extends along an approximately [1-100] direction of said semiconductor element layer.

20. An optical apparatus comprising a nitride-based semiconductor laser element and an optical system controlling light emitted from said nitride-based semiconductor laser element, wherein
said nitride-based semiconductor laser element includes a semiconductor element layer made of a nitride-based semiconductor including a light-emitting layer and having an emitting-side cavity facet and a reflecting-side cavity facet, and a facet coating film formed on said emitting-side cavity facet, and
said facet coating film has a first dielectric film made of aluminum nitride formed in contact with said emitting-side cavity facet, a second dielectric film made of aluminum oxynitride formed on a side of said first dielectric film opposite to said emitting-side cavity facet, a third dielectric film made of aluminum oxide formed on a side of said second dielectric film opposite to said first dielectric film, a fourth dielectric film made of aluminum oxynitride formed on a side of said third dielectric film opposite to said second dielectric film, and a fifth dielectric film made of aluminum oxide formed on a side of said fourth dielectric film opposite to said third dielectric film.
